(19) United States
(12) Patent Application Publication
(10) Pub. No.: US 2025/0219625 A1
(43) Pub. Date: Jul. 3, 2025

(54) CLOCK FILTER SYSTEM AND CLOCK FILTER SWITCHING METHOD

(71) Applicant: NUVOTON TECHNOLOGY CORPORATION, HSINCHU CITY (TW)

(72) Inventor: Yung-Chi Lan, zhubei City (TW)

(21) Appl. No.: 18/982,487

(22) Filed: Dec. 16, 2024

(30) Foreign Application Priority Data
Dec. 29, 2023 (TW) 112151565

(51) Int. Cl. H03K 5/125; H03K 19/20

(52) U.S. Cl. CPC H03K 5/125; H03K 19/20

(57) ABSTRACT

A clock filter system and a clock filter switching method. The clock filter system includes a plurality of clock filters for respectively outputting a plurality of individual clock signals; a bypass circuit for outputting a bypass enable signal; a plurality of clock enable circuits for respectively outputting a plurality of enable signals; a feedback logic circuit for performing an inverse OR (NOR) operation on the bypass enable signal and the plurality of enable signals to generate a feedback signal; a plurality of clock control circuits for respectively generating and outputting a plurality of control signals according to the feedback signal and the plurality of enable signals to respectively control the plurality of individual clock signals to be turned on or turned off. When switching clock filters, a source individual clock signal and a target individual clock signal are controlled to be turned on at different times.

### CROSS-REFERENCE TO RELATED APPLICATION

This application claims the priority from the TW patent application No. 112151565, filed on Dec. 29, 2023, and all contents of such TW Patent Application are comprised in the present disclosure.

### BACKGROUND

### 1. Field of the Invention

The present disclosure relates to clock filter technologies, in particular to, a clock filter system and a clock filter switching method.

### 2. Description of the Related Art

Electronic systems usually reduce operating frequency to save power when computational demand is relatively low (e.g., during standby). In addition to reducing the operating frequency, operating voltage may also be reduced to further reduce power consumption. Accordingly, the cutoff frequency of a clock filter, typically composed of digital circuits, varies with changes in voltage. Specifically, after voltage reduction, the cutoff frequency of the clock filter reduces accordingly. This results in the clock being filtered out by the filter, leading to the unavailability of a usable clock, and consequently causing the circuit to shut down.

In this regard, current designs may use multiplexers or clock switches to switch between different clock filters (with different cutoff frequencies), thereby enabling the filter to operate in scenarios supporting multiple voltages. To avoid (generating) glitches, the architecture using a multiplexer may need to first turn off a clock source and then use the multiplexer to perform switching. However, turning off the clock source is difficult or prohibited in some applications. In addition, while the architecture using a clock switch can avoid (generating) glitches, the limitation is that all clock filters must be turned on (i.e., individual clocks must be turned on); otherwise, switching will fail. Due to the limitation of being unable to turn off the clock filters, the use of more operating voltages requires more clock filters to be turned on, leading to higher power consumption.

Thus, how to design an architecture and method for effectively switching clock filters is a problem to be solved.

### SUMMARY

In order to solve the above technical problems, the present disclosure provides a clock filter system and a clock filter switching method to switch the clock filters effectively and correctly.

Embodiments of the present disclosure provide a clock filter system, including: a plurality of clock filters for respectively outputting a plurality of individual clock signals; a plurality of clock enable circuits, correspondingly electrically connected to the plurality of clock filters, for respectively outputting a plurality of individual output signals and a plurality of enable signals; a feedback logic circuit, electrically connected to the plurality of clock enable circuits, for performing an inverse OR (NOR) operation on the plurality of enable signals to generate a feedback signal; a plurality of clock control circuits, electrically connected to the feedback logic circuit and correspondingly electrically connected to the plurality of clock filters, for respectively generating and outputting a plurality of control signals according to the feedback signal and the plurality of enable signals to respectively control the plurality of individual clock signals to be turned on or turned off; and an output logic circuit, electrically connected to the plurality of clock enable circuits, for performing an OR operation on the plurality of individual output signals to generate an output signal, wherein: when switching clock filters, a source individual clock signal and a target individual clock signal are controlled to be turned on at different times.

Optionally, the plurality of clock control circuits include: a first clock control circuit corresponding to a first clock filter and a first clock enable circuit, wherein: the first clock enable circuit being for generating a first enable signal according to a first individual clock signal, a filter selection signal, and the feedback signal, and the first clock control circuit being for generating a first control signal according to the feedback signal, the first enable signal and an input signal.

Optionally, the first clock control circuit includes: an OR gate for performing an OR operation on the feedback signal and the first enable signal to generate a first filter enable signal, and an AND gate for performing an AND operation on the first filter enable signal and the input signal to generate the first control signal.

Embodiments of the present disclosure provide a clock filter system, including: a plurality of clock filters for respectively outputting a plurality of individual clock signals; a bypass circuit for outputting a bypass output signal and a bypass enable signal; a plurality of clock enable circuits, correspondingly electrically connected to the plurality of clock filters, for respectively outputting a plurality of individual output signals and a plurality of enable signals; a feedback logic circuit, electrically connected to the bypass circuit and the plurality of clock enable circuits, for performing an inverse OR (NOR) operation on the bypass enable signal and the plurality of enable signals to generate a feedback signal; a plurality of clock control circuits, electrically connected to the feedback logic circuit and correspondingly electrically connected to the plurality of clock filters, for respectively generating and outputting a plurality of control signals according to the feedback signal and the plurality of enable signals to respectively control the plurality of individual clock signals to be turned on or turned off; and an output logic circuit, electrically connected to the bypass circuit and the plurality of clock enable circuits, for performing an OR operation on the bypass output signal and the plurality of individual output signals to generate an output signal, wherein: when switching clock filters, a source individual clock signal and a target individual clock signal are controlled to be turned on at different times.

Optionally, the plurality of clock control circuits include: a first clock control circuit corresponding to a first clock filter and a first clock enable circuit, wherein: the first clock enable circuit being for generating a first enable signal according to a first individual clock signal, a filter selection signal, and the feedback signal, and the first clock control circuit being for generating a first control signal according to the feedback signal, the first enable signal and an input signal.

Optionally, the first clock control circuit includes: an OR gate for performing an OR operation on the feedback signal and the first enable signal to generate a first filter enable signal, and an AND gate for performing an AND operation on the first filter enable signal and the input signal to generate the first control signal.

Optionally, the bypass circuit is not directly electrically connected to a clock filter and is for generating the bypass enable signal according to an input signal, a filter selection signal, and the feedback signal.

Optionally, the plurality of clock filters respectively correspond to a plurality of voltages, and the filter selection signal indicates one of a plurality of values, the plurality of values respectively correspond to the bypass circuit and the plurality of voltages, wherein a value corresponding to a highest voltage is encoded using all first logic values, a value corresponding to the bypass circuit is encoded using all second logic values, and a value corresponding to another voltage is encoded using a one hot code.

Embodiments of the present disclosure provide a clock filter switching method, adapted for a clock filter system, the clock filter switching method including: after a triggering event of switching clock filters occurs, setting a selection signal to stop indicating a source clock filter and thereby triggering a source enable signal output by a source clock enable circuit to switch off, and triggering a source control signal output by a source clock control circuit to control the source clock filter to stop outputting a source individual clock signal; and setting the selection signal to start indicating a target clock filter and thereby triggering a target enable signal output by a target clock enable circuit to switch on, and triggering a target control signal output by a target clock control circuit to control the target clock filter to output a target individual clock signal, wherein: a feedback signal is generated by performing an NOR operation on the source enable signal and the target enable signal, the source control signal is generated based on the feedback signal and the source enable signal, and the target control signal is generated based on the feedback signal and the target enable signal.

Optionally, the clock filter switching method further includes: after a triggering event of switching voltages occurs, setting the selection signal to switch to indicate a bypass circuit and thereby triggering the source enable signal to switch off, and triggering a bypass enable signal output by the bypass circuit to switch on; after switching to the bypass circuit, determining whether a target voltage is lower than a source voltage; and if the target voltage is lower than the source voltage, after completing switching to the target voltage, setting the selection signal to switch to indicate the target clock filter and thereby triggering the bypass enable signal to switch off, and triggering the target enable signal to switch on.

Based on the above, the clock filter system and the clock filter switching method provided by the present disclosure may achieve (1) not generating glitches or preventing glitches from entering the system during switching, and (2) turning off unused clock filters during switching (i.e., turning off individual clocks) to reduce power consumption.

### BRIEF DESCRIPTION OF THE DRAWINGS

The drawings are provided to make the persons with ordinary knowledge in the field of the art further understand the present disclosure, and are incorporated into and constitute a part of the specification of the present disclosure. The drawings illustrate demonstrated embodiments of the present disclosure, and are used to explain the principal of the present disclosure together with the description of the present disclosure.

FIG. 1 is a schematic architecture diagram of switching clock filters using a multiplexer;

FIG. 2 is a schematic waveform timing diagram according to FIG. 1;

FIG. 3 is a schematic architecture diagram of switching clock filters using a clock switch;

FIG. 4 is a schematic waveform timing diagram according to FIG. 3;

FIG. 5 is a schematic circuit diagram of a clock filter system according to an embodiment of the present disclosure;

FIG. 6 is a schematic circuit diagram of a clock control circuit of a clock filter system according to an embodiment of the present disclosure;

FIG. 7 is a schematic waveform timing diagram according to FIG. 5;

FIG. 8 is a schematic circuit diagram of a clock filter system according to an embodiment of the present disclosure;

FIG. 9 is a schematic flowchart diagram of a clock filter switching method when changing voltage according to an embodiment of the present disclosure; and

FIG. 10 is a schematic waveform timing diagram according to FIG. 9.

### DESCRIPTION OF THE PREFERRED EMBODIMENTS

To address the above technical problems, embodiments of the present disclosure provide a clock filter system and a clock filter switching method. Reference will now be made in detail to exemplary embodiments of the present disclosure, which will be illustrated in the accompanying drawings. Where possible, the same reference symbols are used in the drawings and the description to refer to the same or similar components. In addition, the implementation of the exemplary embodiment is only one of the realization ways of the design concept of the present disclosure, and the following examples are not intended to limit the present disclosure.

A conventional pulse generator may include a delay chain and an AND gate. The pulse generator which inputs a signal in (not shown in the figure) may perform an AND operation on the (un-delayed) signal in and the delayed signal in to obtain a pulse on the positive edge of the signal in.

A clock filter may include two pulse generators, an inverter, and a latch (e.g., SR latch). The inverter may generate an inverted clock signal clk_in_inv which is inverted from an input clock signal clk_in according to the input clock signal clk_in. The two pulse generators may respectively receive the clock signal clk_in and the inverted clock signal clk_in_inv to generate pulses P_out_1 and P_out_2. The setting input terminal and reset input terminal of the latch may respectively receive the pulses P_out_1 and P_out_2 to generate a clock signal clk_out. The clock signal clk_out is output by a non-inverted output terminal of the latch. It should be noted that when the frequency of the clock signal is too high (e.g., higher than the cutoff frequency of the clock filter), the pulse generator fails to generate pulses. Consequently, the latch cannot transition continuously, causing the output signal to remain in the same state/phase. In other words, this circuit may effectively filter out high-frequency clock signals through the above characteristics.

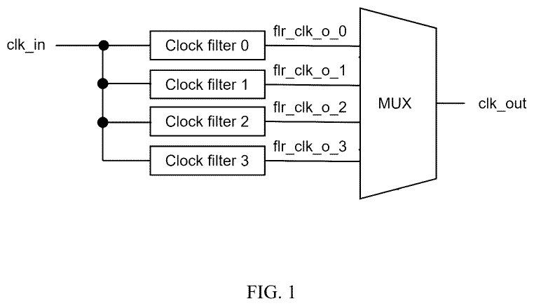

In traditional architecture, when (e.g., if) the system supports or uses multiple voltages (modes), multiple different clock filters (with different cutoff frequencies) may be combined. These filters are then integrated with a multiplexer (MUX) to switch to the appropriate clock filter for the current voltage. Please refer to FIG. 1, which is a schematic architecture diagram of switching clock filters using a multiplexer.

Glitches may occur when the multiplexer switches. To avoid generating glitches, a common practice is to perform switching after the negative edge of individual clock signals (e.g., flr_clk_o_0). The input to each clock filter is from the same source (i.e., clk_in), while the internal delay chains of the clock filters have different lengths. In this case, it is difficult and nearly impossible to align all individual clock signals output by all clock filters to the same phase (e.g., logic value), especially when this feature is required in all voltage modes.

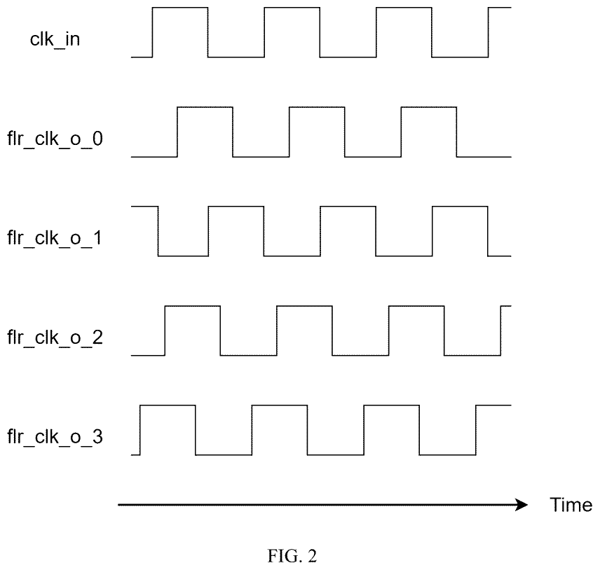

FIG. 2 is a schematic waveform timing diagram according to FIG. 1. As shown in FIG. 2, at a given time point, only a maximum of 3 individual clock signals output by clock filters have the same state, making it impossible to switch when all 4 clock filters output low logic values. Thus, the only way to avoid glitches in this architecture is to first turn off the input signal clk_in, and then switch the clock filters. The input signal clk_in is (re) turned on after the completion of switching the clock filters.

However, in some application scenarios, turning off the input source is not allowed. For example, when (e.g., if) the input clock signal is provided to a central processing unit (CPU), turning off the input clock signal will result in the CPU incapable of performing subsequent operations or instructions.

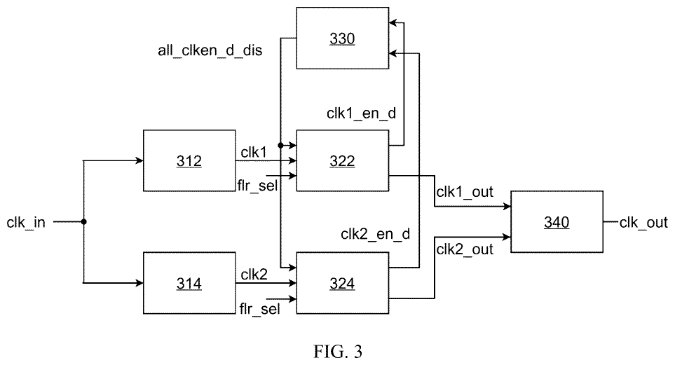

When (e.g., if) the system supports or uses multiple voltages (modes), multiple different clock filters (with different cutoff frequencies) may be combined and then integrated with a clock switch to switch to the clock filter appropriate for the current voltage. Please refer to FIG. 3, which is a schematic architecture diagram of switching clock filters using a clock switch. As shown in FIG. 3, the clock switch is electrically connected to two clock filters 312 and 314 to respectively receive two input clocks, clk1 and clk2. The clock switch switches between the input clocks with different phases without generating glitches. In this architecture, each clock source (e.g., input clock signal clk0) corresponds to/matches a single enable signal (e.g., enable signal clk0_en_d), and each enable signal clk_en_d controls whether the corresponding clock is released.

It should be noted that although the (filter) selection signal flr_sel in FIG. 3 indicates the clock filter to be used/switched through an inverter, it may also be implemented through encoding. For example, when the selection signal flr_sel indicates a first value (e.g., 00), it means the use of clock filter 312; when the selection signal flr_sel indicates a second value (e.g., 11), it means the use of clock filter 314.

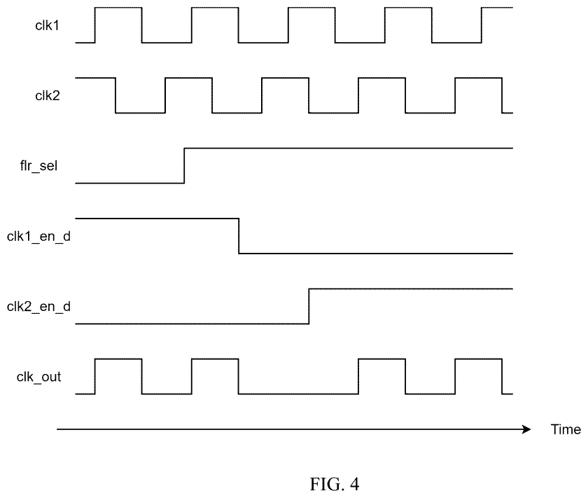

FIG. 4 is a schematic waveform timing diagram according to FIG. 3. As shown in FIG. 4, in this architecture, at a given time point, only a maximum of 1 enable signal clk_en_d is in a high logic state, indicating that at most one clock is released at the same time. Since each enable signal clk_en_d transitions on the negative edge of the corresponding clock signal, no glitches are generated.

However, since all enable signals clk_en_d transition on the negative edge of the corresponding clock signals, it means that both the source clock (e.g., clk0) and the target clock (e.g., clk1) must exist when the clock switch switches clocks. Otherwise, the enable signal clk_en_d cannot transition, and the switching operation cannot be completed. In other words, the clock switch needs to continuously output individual clocks to perform switching. Thus, the clock gating cannot be performed (i.e., individual clocks cannot be properly turned off). Since all inputs are electrically connected to the corresponding clock filters, which include delay chains. Consequently, the entire delay chain keeps transitioning when the clock passes through the clock filter, leading to high power consumption.

When (e.g., if) the system supports or uses multiple voltages (modes), multiple clock filters designed according to these multiple voltages may be combined to achieve multi-voltage operation. It should be noted that the cutoff frequency of each clock filter varies with changes in voltage.

Table 1 shows the correspondence relation between multiple clock filters and multiple voltages.

TABLE 1

| Clock | Delay chain | | | | | |
|---|---|---|---|---|---|---|
| filter | length | 1.2 v | 1.1 v | 1.0 v | 0.9 v | |
| 0 | Short | 50 MHz | 36 MHz | 20 MHz | 12 | MHz |
| 1 | Medium | 40 MHz | 24 MHz | 12 MHz | 6 | MHz |
| 2 | Long | 20 MHz | 12 MHz | 8 MHz | 1 | MHz |
| 3 | Longest | 12 MHz | 8 MHz | 6 MHz | 500 | kHz |

As shown in Table 1, the filter is designed with a cutoff frequency of 12 MHz and to support four voltage levels. Clock filter 3 has a longer delay chain and is used when the operating voltage is 1.2 v. Clock filter 2 is used when the operating voltage is 1.1 v. Clock filter 1 is used when the operating voltage is 1.0 v. Clock filter 0 has a shorter delay chain and is used when the operating voltage is 0.9 v. In other words, at the same (cutoff) frequency, clock filter 3 corresponds to a higher voltage, while clock filter 0 corresponds to a lower voltage. These four clock filters may be low-pass filters. It should be noted that Table 1 is for illustrative purposes only and is not intended to limit the present disclosure.

It should be noted that when a clock filter corresponding to a higher voltage is used in a lower voltage scenario, the cutoff frequency of that clock filter decreases, causing the clocks originally falling within the normal frequency band to be filtered out. For example, when clock filter 3 is used at 1.2 v, the cutoff frequency is 12 MHz. When clock filter 3 is used at 0.9 v, the cutoff frequency decreases to 500 kHz, causing the clocks originally falling within the normal frequency band to be filtered out. In contrast, when a clock filter corresponding to a lower voltage is used in a higher voltage scenario, the cutoff frequency of that clock filter increases, and the clocks originally falling within the normal frequency band will not be filtered out.

The system may use the selection signal flr_sel to indicate (e.g., switch) the filter mode to be used. This signal and the input signal are in an asynchronous relation. Table 2 shows the correspondence between filter modes and selection signals.

TABLE 2

| Mode | Value indicated by the selection signal |
|---|---|
| Clock filter 0 (0.9 v) | 3′b001 |
| Clock filter 1 (1.0 v) | 3′b010 |
| Clock filter 2 (1.1 v) | 3′b011 |
| Clock filter 3 (1.2 v) | 3′b100 |

As shown in Table 2, the value 3′b001 corresponds to clock filter 0 (corresponding to the lower voltage of 0.9 v), and the value 3′b100 corresponds to clock filter 3 (corresponding to the higher voltage of 1.2 v).

Asynchronous issues may cause circuit failures. For example, when the system switches the voltage from 1.0 v to 0.9 v, the selection signal flr_sel will ideally change from 3′b010 to 3′b001. However, since each bit path is different, (asynchronous) transient values may occur. When bit 0 changes faster than bit 1, a transient value of 3′b011 may occur, causing the filter to incorrectly switch to the filter mode corresponding to 1.1 v. The initial voltage during the conversion is 1.0 v, and the filter corresponding to 1.1 v theoretically will filter out the clocks (e.g., with frequencies higher than 8 MHz) (to avoid switching to 1.1 v). However, in actual chip production, depending on process-voltage-temperature (PVT) variations, the filter corresponding to 1.1 v may not filter out the clocks at 1.0 v. As the voltage drops to the target voltage of 0.9 v, the filter corresponding to 1.1 v may filter out the clocks at 0.9 v, causing the enable signal clk_en_d to have no clock to operate (to release or not). In this case, even if the transient value of the selection signal flr_sel disappears (i.e., changes to a steady state value of 001), the filter cannot successfully switch to the 0.9 v mode.

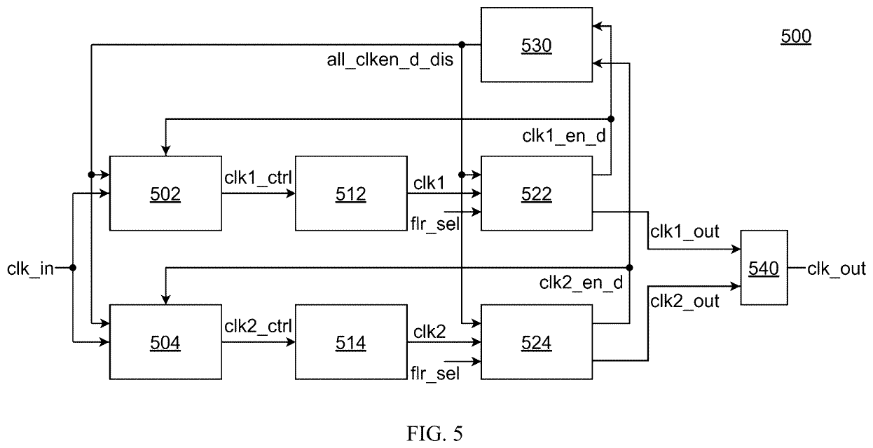

FIG. 5 is a schematic circuit diagram of a clock filter system according to an embodiment of the present disclosure. As shown in FIG. 5, the clock filter system 500 includes a plurality of clock filters 512-514, a plurality of clock enable circuits 522-524, a feedback logic circuit 530, a plurality of clock control circuits 502-504, and an output logic circuit 540.

The plurality of clock filters 512-514 are for respectively outputting a plurality of individual clock signals clk1-clk2. The plurality of clock enable circuits 522-524 are correspondingly electrically connected to the plurality of clock filters 512-514. The plurality of clock enable circuits 522-524 are for respectively receiving the plurality of individual clock signals clk1-clk2 and respectively outputting a plurality of individual output signals clk1_out-clk2_out. In addition, the plurality of clock enable circuits 522-524 are for respectively outputting a plurality of enable signals clk1_en_d-clk2_en_d to respectively control the release (status) of the plurality of individual clock signals clk1-clk2. The feedback logic circuit 530 is electrically connected to the plurality of clock enable circuits 522-524. The feedback logic circuit 530 is for receiving the plurality of enable signals clk1_en_d-clk2_en_d and performing NOR operation on the plurality of enable signals clk1_en_d-clk2_en_d to generate a feedback signal all_clken_d_dis. The plurality of clock control circuits 502-504 are electrically connected to the feedback logic circuit and correspondingly electrically connected to the plurality of clock filters 512-514. The plurality of clock control circuits 502-504 are for receiving the feedback signal all_clken_d_dis and respectively receiving the plurality of multiple enable signals clk1_en_d-clk2_en_d. The plurality of clock control circuits 502-504 are for respectively generating and outputting, according to the feedback signal all_clken_d_dis and the plurality of enable signals clk1_en_d-clk2_en_d, a plurality of control signals clk1_ctrl-clk2_ctrl to respectively control the plurality of individual clock signals clk1-clk2 to be turned on or turned off. In other words, the control signals are for controlling the corresponding clock filters to (start) output or stop outputting individual clock signals. For example, when the control signal is a high logic value, the corresponding clock filter outputs an individual clock signal. When the control signal is a low logic value, the corresponding clock filter stops outputting the individual clock signal. The output logic circuit 540 is electrically connected to multiple clock enable circuits 522-524. The output logic circuit 540 is for receiving the plurality of individual output signals clk1_out-clk2_out and performing OR operation on the plurality of individual output signals clk1_out-clk2_out to generate the output signal clk_out. When switching clock filters, a source individual clock signal and a target individual clock signal are controlled to be turned on at different times (e.g., both are low logic values, or only one is a high logic value).

As described above, each clock control circuit has clock gating functionality and may be served as a clock gater, and the enable logic of its clock gating unit is generated from two signal paths.

The selection signal flr_sel may indicate one of a plurality of values. The plurality of values may respectively correspond to the plurality of clock filters 512-514. For example, when the selection signal flr_sel indicates a first value (e.g., 000), it indicates the use of the clock filter 512. Accordingly, the selection signal flr1_sel (not separately shown in the figure) input to the clock enable circuit 522 is a high logic value, and the selection signal flr2_sel (not separately shown in the figure) input to the clock enable circuit 524 is a low logic value. When the selection signal flr_sel indicates a second value (e.g., 001), it indicates the use of the clock filter 514. Accordingly, the selection signal flr1_sel input to the clock enable circuit 522 is a low logic value, and the selection signal flr2_sel input to the clock enable circuit 524 is a high logic value.

In addition, the selection signal flr2_sel may be generated according to an inverter and the selection signal flr1_sel. For example, the selection signal flr1_sel passing through the inverter may be (equivalent to) the selection signal flr2_sel.

It should be noted that the total number of filter circuits/modes in FIG. 5 is 2, which is for illustrative purposes only and is not intended to limit the present disclosure.

In some embodiments, the plurality of clock control circuits 502-504 may include a first clock control circuit (“clock control circuit 502” is exemplified for description in the following) corresponding to the first clock filter (“clock filter 512” is exemplified for description in the following) and the first clock enable circuit (“clock enable circuit 522” is exemplified for description in the following). The first clock enable circuit 522 may be for generating the first enable signal clk1_en_d according to the first individual clock signal clk1, the filter selection signal flr_sel, and the feedback signal all_clken_d_dis. The first clock control circuit 502 may be for generating the first control signal clk1_ctrl according to the feedback signal all_clken_d_dis, the first enable signal clk1_en_d, and the input signal clk_in.

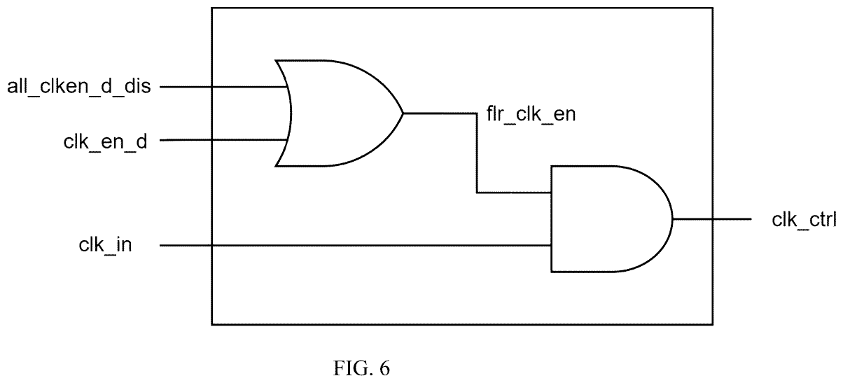

FIG. 6 is a schematic circuit diagram of a clock control circuit (“clock control circuit 502” is exemplified for description in the following) of a clock filter system according to an embodiment of the present disclosure. As shown in FIG. 6, the first clock control circuit 502 may include an OR gate and an AND gate. The OR gate may be for performing OR operation on the feedback signal all_clken_d_dis and the first enable signal clk1_en_d to generate the first filter enable signal flr1_clk_en. The AND gate may be for performing AND operation on the first filter enable signal flr1_clk_en and the input signal clk_in to generate the first control signal clk1_ctrl.

It should be noted that the paths between the enable signal clk_en_d and the input signal clk_in pass through the clock filter, so it is difficult for the two to achieve synchronization. In this case, the AND gate may possibly generate glitches. However, the glitches generated by the AND gate will be filtered out after entering the clock filter, and thus there is no need to consider timing balance.

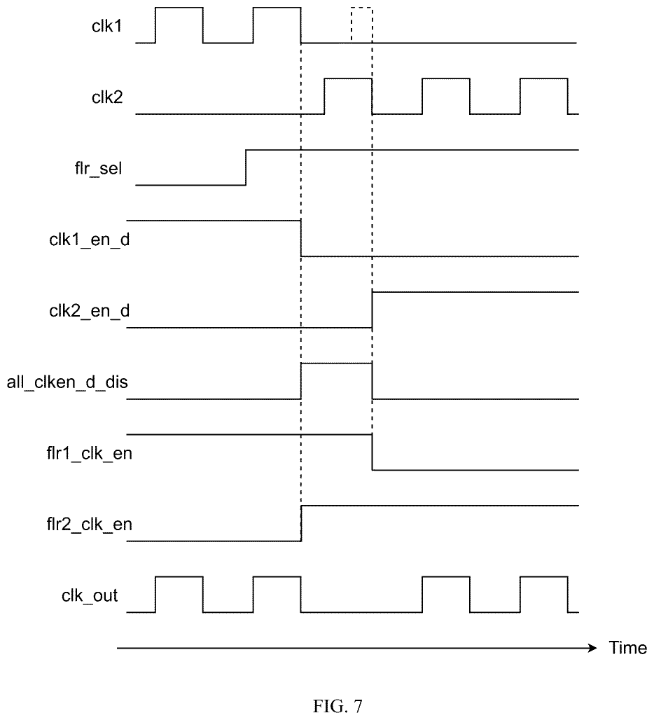

FIG. 7 is a schematic waveform timing diagram according to FIG. 5. As shown in FIG. 7, the selection signal flr_sel indicates a switch from using the source clock clk1 to using the target clock clk2. According to the source filter enable signal flr1_clk_en (and the corresponding control signal clk1_ctrl), the source clock filter 512 is controlled to stop outputting the source individual clock clk1 (i.e., the source clock clk1 is properly turned off instead of being turned on continuously) to achieve power saving. According to the target filter enable signal flr2_clk_en (and the corresponding control signal clk1_ctr2), the target clock filter 514 is controlled to start outputting the target individual clock clk2 (i.e., the target clock clk2 is properly turned on instead of being turned on continuously) to achieve power saving. It should be noted that even though the AND gate generates glitches (illustrated by dashed lines) according to the clock signal and the filter enable signal, these glitches will be filtered out after inputting to the clock filter.

When the first enable signal clk1_en_d is a high logic value, it indicates that the first clock clk1 is released. When the feedback signal all_clken_d_dis is a high logic value, it indicates that the plurality of clocks are not released (thereby triggering the target clock filter to perform switching).

In some embodiments, the feedback logic circuit may only include the NOR gate. The NOR gate is for performing NOR operation on the plurality of enable signals clk1_en_d-clk2_en_d to generate the feedback signal all_clken_d_dis.

In some embodiments, the output logic circuit may only include the OR gate. The OR gate is for performing OR operation on the plurality of individual output signals clk1_out-clk2_out to generate the output signal clk_out.

In some embodiments, the first clock enable circuit 522 may include the AND gate. The AND gate is for performing AND operation on the first individual clock signal clk1 and the first enable signal clk1_en_d to generate the first individual output signal clk1_out. In some embodiments, the first enable signal clk1_en_d may be a delay of another signal. Specifically, the first clock enable circuit 522 may further include a first (D-type) flip-flop, a second (D-type) flip-flop, and an inverter. According to the first individual clock signal clk1, the selection signal flr_sel, and the feedback signal all_clken_d_dis, the first flip-flop may generate a first enable non-delayed signal clk1_en. According to the first enable non-delayed signal clk1_en and the first individual clock signal clk1 passing through the inverter, the second flip-flop may generate the delayed first enable signal clk1_en_d. In some embodiments, the first clock enable circuit 522 may further include the OR gate and a multiplexer.

In some embodiments, the feedback signal all_clken_d_dis and the input signal clk_in may be asynchronous. In some embodiments, the selection signal flr_sel and the input signal clk_in may be asynchronous.

In some embodiments, the plurality of clock filters 512-514 may correspond to a plurality of voltages at the same cutoff frequency. In some embodiments, the plurality of clock filters 512-514 may respectively correspond to a plurality of delay chains of different lengths.

In some embodiments, after the selection signal switches to indicate the target clock filter, the source enable signal transitions on the negative edge of the source individual clock signal. In some embodiments, after the selection signal switches to indicate the target clock filter, the target enable signal transitions on the negative edge of the target individual clock signal.

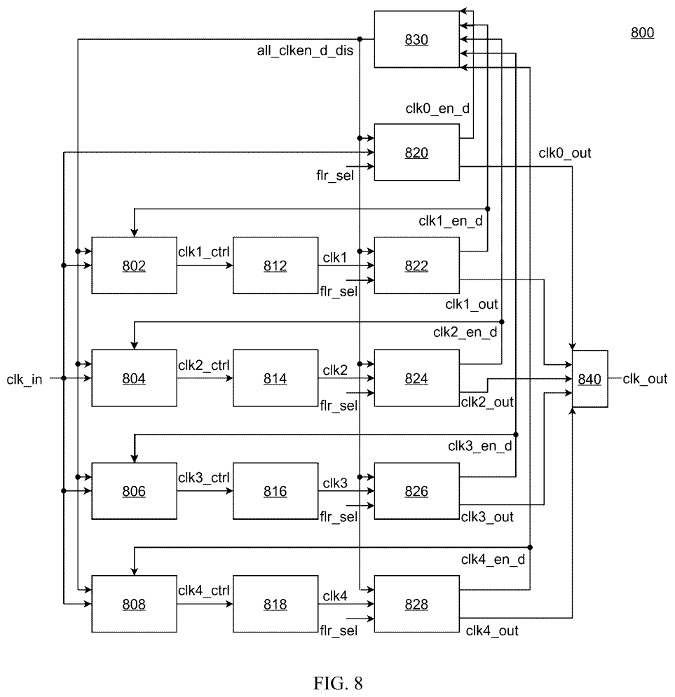

FIG. 8 is a schematic circuit diagram of a clock filter system according to an embodiment of the present disclosure. As shown in FIG. 8, the clock filter system 800 includes a plurality of clock filters 812-818, a bypass circuit 820, a plurality of clock enable circuits 822-828, a feedback logic circuit 830, a plurality of clock control circuits 802-808, and an output logic circuit 840.

The plurality of clock filters 812-818 are for respectively outputting a plurality of individual clock signals clk1-clk4. The bypass circuit 820 is for outputting a bypass output signal clk0_out and a bypass enable signal clk0_en_d. The plurality of clock enable circuits 822-828 are correspondingly electrically connected to the plurality of clock filters 812-818. The plurality of clock enable circuits 822-828 are for respectively receiving the plurality of individual clock signals clk1-clk4 and outputting the plurality of individual output signals clk1_out-clk4_out. In addition, the plurality of clock enable circuits 822-828 are for respectively outputting the plurality of enable signals clk1_en_d-clk4_en_d to control the release (status) of the plurality of individual clock signals clk1-clk4. The feedback logic circuit 830 is electrically connected to the bypass circuit 820 and the plurality of clock enable circuits 822-828. The feedback logic circuit 830 is for receiving the bypass enable signal clk0_en_d and the plurality of enable signals clk1_en_d-clk4_en_d. In addition, the feedback logic circuit 830 is for performing a NOR operation on the bypass enable signal clk0_en_d and the plurality of enable signals clk1_en_d-clk4_en_d to generate a feedback signal all_clken_d_dis. The plurality of clock control circuits 802-808 are electrically connected to the feedback logic circuit and correspondingly electrically connected to the plurality of clock filters 812-818. The plurality of clock control circuits 802-808 are for receiving the feedback signal all_clken_d_dis and respectively receiving the plurality of enable signals clk1_en_d-clk4_en_d. In addition, the plurality of clock control circuits 802-808 are for respectively generating and outputting, according to the feedback signal all_clken_d_dis and the plurality of enable signals clk1_en_d-clk4_en_d, a plurality of control signals clk1_ctrl-clk4_ctrl to respectively control the plurality of individual clock signals clk1-clk4 to be turned on or turned off. In other words, the control signals are for controlling the corresponding clock filters to (start) output or stop outputting individual clock signals. For example, when the control signal is a high logic value, the corresponding clock filter starts outputting the individual clock signal. When the control signal is a low logic value, the corresponding clock filter stops outputting the individual clock signal. The output logic circuit 840, electrically connected to the bypass circuit 820 and the plurality of clock enable circuits 822-828, is for receiving the bypass output signal clk0_out and the plurality of individual output signals clk1_out-clk4_out. The output logic circuit 840 is for performing an OR operation on the bypass output signal clk0_out and the plurality of individual output signals clk1_out-clk4_out to generate an output signal clk_out. When switching clock filters, a source individual clock signal and a target individual clock signal are controlled to be turned on at different times (e.g., both are low logic values simultaneously, or only one is a high logic value).

In some embodiments, the bypass circuit 820 may not be directly electrically connected to the clock filters. That is, the bypass circuit 820 operates as a bypass mode without filtering functionality. The bypass circuit 820 may be for generating the bypass enable signal clk0_en_d according to the input signal clk_in, the filter selection signal flr_sel, and the feedback signal all_clken_d_dis.

In some embodiments, the clock filter system (e.g., feedback logic circuit 830) may receive a bypass acknowledgment (ack) signal indicating the operating status of the bypass circuit. When the bypass ack signal is a high logic value, it indicates operating in (or switching to) the bypass circuit (mode). The bypass enable signal and the bypass ack signal may be aligned in time (e.g., both are high logic values simultaneously).

The configurations and operations of the clock filters (e.g., clock filters 812-818), clock enable circuits (e.g., clock enable circuits 822-828), and clock control circuits (e.g., clock control circuits 802-808) in this embodiment are similar to those of the clock filters (e.g., clock filters 512-514), clock enable circuits (e.g., clock enable circuits 522-524), and clock control circuits (e.g., clock control circuits 502-504) described above. Thus, relevant descriptions may be referred to the description of the above embodiments, and are not repeated herein.

In addition to the bypass mode, each mode may gate the filter (e.g., by using an AND gate) to achieve power saving. The AND gate may generate a control signal clk_ctrl according to the filter enable signal flr_clk_en. The filter enable signal flr_clk_en includes components/factors of the enable signal clk_en_d on which the NOR operation is performed. Since the filter enable signal flr_clk_en and the input signal clk_in are asynchronous, these two signals may generate glitches after passing through the AND gate.

The bypass mode not configured with a clock filter cannot filter out glitches. To avoid being unable to filter out possible glitches, the path of the bypass mode cannot use an AND gate to gate the clocks passing through the bypass circuit (e.g., through a flip-flop). However, since the bypass mode does not have a delay chain and does not generate high power consumption, it does not necessarily require a clock gating mechanism.

In some embodiments, the plurality of clock filters 812-818 may respectively correspond to a plurality of voltages, and the selection signal flr_sel may indicate one of a plurality of values. The plurality of values may respectively correspond to the bypass circuit 820 and the plurality of voltages (i.e., the plurality of clock filters 812-818). The value corresponding to the highest voltage is encoded as/using all a first logic value. The value corresponding to the bypass circuit 820 is encoded as/using all a second logic value. The values corresponding to other voltages are encoded as/using one hot code. The above encoding method may not only avoid asynchronous problems causing the clock filter to enter an incorrect state/value but also improve encoding efficiency.

It should be noted that the total number of filter circuits/modes in FIG. 8 is 4, which is for illustrative purposes only and is not intended to limit the present disclosure.

In some embodiments, the length of the value (e.g., the total number of bits) indicated by the selection signal depends on the total number of the filter modes (e.g., clock filters and/or operable voltages).

Table 3 is a coding manner for the selection signal.

TABLE 3

| Mode | Value indicated by the selection signal |
|---|---|
| Bypass mode | 3′b000 |
| Clock filter 0 (0.9 v) | 3′b001 |
| Clock filter 1 (1.0 v) | 3′b010 |
| Clock filter 2 (1.1 v) | 3′b100 |
| Clock filter 3 (1.2 v) | 3′b111 |

As shown in Table 3, the bypass mode may be encoded as/using all 0s, the filter mode corresponding to a higher operating voltage (e.g., corresponding to a longer delay chain) may be encoded as/using all 1s, and the remaining filter modes use one-hot code to further reduce the total number of used logical values.

Table 4 is another coding manner for the selection signal.

TABLE 4

| Mode | Value indicated by the selection signal |
|---|---|
| Bypass mode | 3′b111 |
| Clock filter 0 (0.9 v) | 3′b001 |
| Clock filter 1 (1.0 v) | 3′b010 |
| Clock filter 2 (1.1 v) | 3′b100 |
| Clock filter 3 (1.2 v) | 3′b000 |

As shown in Table 4, the bypass mode may be encoded as/using all 1s, the filter mode corresponding to a higher operating voltage (e.g., corresponding to a longer delay chain) may be encoded as/using all 0s, and the remaining filter modes use one-hot code to further reduce the total number of used logical values

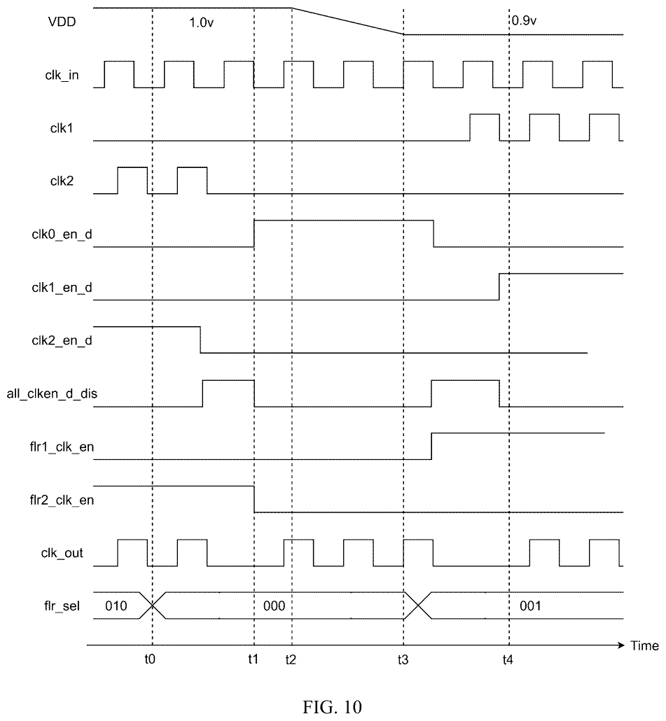

FIG. 9 is a schematic flowchart diagram of a clock filter switching method when changing voltage according to an embodiment of the present disclosure. This clock filter method may be applied in the clock filter system described above. As shown in FIG. 9, this clock filter method includes the following steps:

In step S902, a triggering event of switching voltages (e.g., the system transmits a request for adjusting the voltage) occurs and a triggering event of switching clock filters occurs.

In step S904, set the clock filter system to switch from the source filter mode to the bypass mode (i.e., a mode without filtering function). Specifically, the selection signal flr_sel may be set to switch from (implicitly) indicating the source clock filter to (implicitly) indicate the bypass circuit. This triggers the source enable signal output by the source clock enable circuit to switch off, triggers the source control signal output by the source clock control circuit to control the source clock filter to stop outputting the source individual clock signal, and triggers the bypass enable signal output by the bypass circuit to switch on. The feedback signal is generated by performing NOR operation on the source enable signal and the target enable signal (e.g., through feedback logic circuit). The source control signal is generated according to the feedback signal and the source enable signal.

In step S906, after switching to the bypass mode (e.g., when the system receives a bypass ack signal), perform voltage changes (e.g., by sending a request for adjusting the voltage to the voltage regulator).

In step S908, determine whether a target voltage is lower than a source voltage. If yes, proceed to step S910; if no, proceed to step S912. That is, the subsequent operations are determined according to operation type (i.e., boost or buck).

In step S910, the switch from the source voltage to the target voltage is completed. In other words, the voltage state has stabilized.

In step S912, set the clock filter system to switch from the bypass mode to the target filter mode. Specifically, the selection signal flr_sel may be set to switch from (implicitly) indicating the bypass circuit to (implicitly) indicate the target clock filter. This triggers the bypass enable signal to switch off, triggers the target enable signal output by the target clock enable circuit to switch on, and triggers the target control signal output by the target clock control circuit to control the target clock filter to turn on outputting the target individual clock signal. The target control signal is generated according to the feedback signal and the target enable signal.

As described above, if the buck operation is performed, the clock filter mode should be changed after the voltage conversion (i.e., step S910) is completed. The reason is that if the voltage is not reduced enough, the cutoff frequency may still be in a higher frequency range. In this case, if a glitch occurs due to asynchronization issues, the filter may not be able to filter out the glitch, and the system failure may accordingly occur.

If the boost operation is performed, the clock filter mode may be changed directly regardless of whether the voltage conversion is completed. To simplify the complexity of the circuit, the clock filter mode may be changed after the voltage conversion regardless of whether the boost operation or the buck operation is performed.

In addition, the output signal is generated through the output logic circuit according to the bypass enable signal, the input signal, the source enable signal, the source individual clock signal, the target enable signal, and the target individual clock signal.

It should be noted that the operating order of the above steps is for illustrative purposes only and is not intended to limit the present disclosure.

FIG. 10 is a schematic waveform timing diagram according to FIG. 9.

At time point t0, a triggering event of switching voltages occurs (e.g., when the system receives a command to adjust the voltage). Set/configure the clock filter system to enter/switch to the bypass mode (e.g., by setting the selection signal flr_sel=000).

At time point t1, the clock filter system has switched to the bypass mode (e.g., when the system receives a bypass ack signal set to a high logic value).

At time point t2, perform a buck operation (e.g., when the system transmits a buck request to the voltage regulator).

At time point t3, the voltage has dropped to 0.9 v, and set the clock filter system to the 0.9 v target filter mode (e.g., by setting the selection signal flr_sel=001).

It should be noted that if the time point of switching the clock filter to the 0.9 v mode is before the completion of voltage conversion (i.e., before voltage VDD drops to 0.9 v), the cutoff frequency of the 0.9 v mode will increase because the voltage is still high (higher than the target voltage). The selection signal flr_sel and the input signal clk_in do not easily achieve asynchronous timing balance. This may cause the generation of glitches (not illustrated in the figure) before the input to the 0.9 v mode clock filter. The cutoff frequency increases due to the higher voltage, making it possible for glitches to enter the system. Thus, in the voltage conversion process, if the buck operation is performed, the switching time point of clock filter modes should be performed after voltage stabilization (i.e., after voltage conversion is completed).

It should be noted that the boost operation does not have this limitation. Before the boost operation, the source voltage is lower, resulting in a lower cutoff frequency of the clock filter. Accordingly, glitches generated by the switching may be filtered out. In addition, before switching modes, it first switch to the bypass mode (i.e., the selection signal flr_sel is all 0s) and then switch to the specified filter mode. Except for the highest voltage setting, where the selection signal flr_sel is all 1s, the rest filter modes are represented by a single bit of 1. Accordingly, incorrect transient values do not occur/can be avoided.

When switching to the highest voltage mode, if an incorrect transient value occurs and the mode is incorrectly switched to another mode, where the cutoff frequencies of other modes are higher at the highest voltage, the clock will not be filtered out. The switching can continue when clocks are present. After the transient value disappears in the next cycle, it may switch to the highest voltage operating mode. This encoding method not only reduces the total number of bits used compared to using only one-hot code but also enhances safety.

To sum up, the clock filter system and the clock filter switching method provided by the present disclosure may achieve (1) not generating glitches or preventing glitches from entering the system during switching, and (2) turning off unused clock filters during switching (i.e., turning off individual clocks) to reduce power consumption. Thus, the issues, such as the traditional clock switch cannot perform clock gating, and the configured clock gate controller cannot easily handle clock domain crossing (CDC), can be solved.

It should be understood that the examples and the embodiments described herein are for illustrative purpose only, and various modifications or changes in view of them will be suggested to those skilled in the art, and will be comprised in the spirit and scope of the application and the appendix with the scope of the claims.

What is claimed is:

1. A clock filter system, comprising:
a plurality of clock filters for respectively outputting a plurality of individual clock signals;
a plurality of clock enable circuits, correspondingly electrically connected to the plurality of clock filters, for respectively outputting a plurality of individual output signals and a plurality of enable signals;
a feedback logic circuit, electrically connected to the plurality of clock enable circuits, for performing an inverse OR (NOR) operation on the plurality of enable signals to generate a feedback signal;
a plurality of clock control circuits, electrically connected to the feedback logic circuit and correspondingly electrically connected to the plurality of clock filters, for respectively generating and outputting a plurality of control signals according to the feedback signal and the plurality of enable signals to respectively control the plurality of individual clock signals to be turned on or turned off; and
an output logic circuit, electrically connected to the plurality of clock enable circuits, for performing an OR operation on the plurality of individual output signals to generate an output signal, wherein:
when switching clock filters, a source individual clock signal and a target individual clock signal are controlled to be turned on at different times.

2. The clock filter system according to the claim 1, wherein the plurality of clock control circuits comprise a first clock control circuit corresponding to a first clock filter and a first clock enable circuit, wherein:
the first clock enable circuit being for generating a first enable signal according to a first individual clock signal, a filter selection signal, and the feedback signal, and
the first clock control circuit being for generating a first control signal according to the feedback signal, the first enable signal and an input signal.

3. The clock filter system according to the claim 2, wherein the first clock control circuit comprises:
an OR gate for performing an OR operation on the feedback signal and the first enable signal to generate a first filter enable signal, and
an AND gate for performing an AND operation on the first filter enable signal and the input signal to generate the first control signal.

4. A clock filter system, comprising:
a plurality of clock filters for respectively outputting a plurality of individual clock signals;
a bypass circuit for outputting a bypass output signal and a bypass enable signal;
a plurality of clock enable circuits, correspondingly electrically connected to the plurality of clock filters, for respectively outputting a plurality of individual output signals and a plurality of enable signals;
a feedback logic circuit, electrically connected to the bypass circuit and the plurality of clock enable circuits, for performing an inverse OR (NOR) operation on the bypass enable signal and the plurality of enable signals to generate a feedback signal;
a plurality of clock control circuits, electrically connected to the feedback logic circuit and correspondingly electrically connected to the plurality of clock filters, for respectively generating and outputting a plurality of control signals according to the feedback signal and the plurality of enable signals to respectively control the plurality of individual clock signals to be turned on or turned off; and
an output logic circuit, electrically connected to the bypass circuit and the plurality of clock enable circuits, for performing an OR operation on the bypass output signal and the plurality of individual output signals to generate an output signal, wherein:
when switching clock filters, a source individual clock signal and a target individual clock signal are controlled to be turned on at different times.

5. The clock filter system according to the claim 4, wherein the plurality of clock control circuits comprise a first clock control circuit corresponding to a first clock filter and a first clock enable circuit, wherein:
the first clock enable circuit being for generating a first enable signal according to a first individual clock signal, a filter selection signal, and the feedback signal, and
the first clock control circuit being for generating a first control signal according to the feedback signal, the first enable signal and an input signal.

6. The clock filter system according to the claim 5, wherein the first clock control circuit comprises:
an OR gate for performing an OR operation on the feedback signal and the first enable signal to generate a first filter enable signal, and
an AND gate for performing an AND operation on the first filter enable signal and the input signal to generate the first control signal.

7. The clock filter system according to the claim 4, wherein the bypass circuit is not directly electrically connected to a clock filter and is for generating the bypass enable signal according to an input signal, a filter selection signal, and the feedback signal.

8. The clock filter system according to the claim 6, wherein the plurality of clock filters respectively correspond to a plurality of voltages, and the filter selection signal indicates one of a plurality of values, the plurality of values respectively correspond to the bypass circuit and the plurality of voltages, wherein:
a value corresponding to a highest voltage is encoded using all first logic values,
a value corresponding to the bypass circuit is encoded using all second logic values, and
a value corresponding to another voltage is encoded using a one hot code.

9. A clock filter switching method, adapted for a clock filter system, the clock filter switching method comprising:
after a triggering event of switching clock filters occurs, setting a selection signal to stop indicating a source clock filter and thereby triggering a source enable signal output by a source clock enable circuit to switch off, and triggering a source control signal output by a source clock control circuit to control the source clock filter to stop outputting a source individual clock signal; and
setting the selection signal to start indicating a target clock filter and thereby triggering a target enable signal output by a target clock enable circuit to switch on, and triggering a target control signal output by a target clock control circuit to control the target clock filter to output a target individual clock signal, wherein:
a feedback signal is generated by performing an NOR operation on the source enable signal and the target enable signal,
the source control signal is generated based on the feedback signal and the source enable signal, and
the target control signal is generated based on the feedback signal and the target enable signal.

10. The clock filter switching method according to the claim 9, further comprising:
after a triggering event of switching voltages occurs, setting the selection signal to switch to indicate a bypass circuit and thereby triggering the source enable signal to switch off, and triggering a bypass enable signal output by the bypass circuit to switch on;
after switching to the bypass circuit, determining whether a target voltage is lower than a source voltage; and
if the target voltage is lower than the source voltage, after completing switching to the target voltage, setting the selection signal to switch to indicate the target clock filter and thereby triggering the bypass enable signal to switch off, and triggering the target enable signal to switch on.
